(19) United States
(12) Patent Application Publication
(10) Pub. No.: US 2018/0301647 A1
(43) Pub. Date: Oct. 18, 2018

(54) Film Technologies Processes and Production of Products Thereby

(71) Applicant: Scott Hohulin Family 2014 Irrevocable Trust, Wildomar, CA (US)

(72) Inventor: Scott Conrad Hohulin, Wildomar, CA (US)

(21) Appl. No.: 15/942,432

(22) Filed: Mar. 31, 2018

Related U.S. Application Data
(60) Provisional application No. 62/479,719, filed on Mar. 31, 2017.

(51) Int. Cl. H01L 51/42; H01L 51/00; H01L 51/44

(52) U.S. Cl. CPC H01L 51/4253; H01L 51/0004; H01L 51/0021; H01L 51/0029; H01L 51/0047; H01L 51/442; H01L 2251/305; H01L 51/0037; H01L 51/0035; H01L 51/0097

(57) ABSTRACT

Novel enhanced 3D films for absorption of light at multiplicities of different wave-lengths for plethoric applications and fabricated several different ways offer for consideration novel paradigms. 3D film is definitionally a holder of an extra dimension. Normal film has length and width it's “depth” is usually minimal based on layers and substrates. 3D film is significantly greater. It holds equal width depth and length with activity on all aspects of the film generating greater charge per mm³. Finished Cubic film is then aligned inside a capturing glass based upon energy band gaps to be captured, for energy between at least about 100 nm to 7000 nm in preferred embodiments, inter alia.

### CROSS-REFERENCE TO RELATED APPLICATIONS

This application claims the benefit of, and priority to U.S. Provisional Patent Application Ser. No. 62/479,719, filed Mar. 31, 2017, the content of which is incorporated herein by reference herein in its entirely. The following application expressly incorporates by reference, as if fully set forth herein commonly owned PCT/US2015/032148 (WO2015/179745); U.S. 62/024,305 (Jul. 14, 2014); UK Patent Application GB 2540309 (published Jan. 11, 2017); U.S. 2017/0077867 A1 (Ser. No. 15/308,088).

Likewise, each patent and claims set incorporated expressly herein, namely each and every one listed, excerpted or produced in full, from the appendix has been relied upon and differentiated such that it represents the state of the art upon which the instant application shows is the state of the art around but not within the pillars of which the instant inventions are emplaced, it is respectfully submitted.

### FIELD

The present disclosures relate to the fields of blue technology, namely providing energy by conversion of Electro-Magnetic radiation of any form from the full spectrum into electricity, inter alia.

### BACKGROUND OF THE DISCLOSURES

There has become known a three step process, among the prior art—for example, for converting sunlight into energy, first photons are absorbed into a material, second photo-induced charge separation takes place and then charges are collected at electrodes. The fourth step was three-dimensionalizing energy harvesting and capture. 3D-Films of the present invention embody this.

It is respectfully proposed that underlying film technologies offered for consideration herein can now do so on an industrially efficient scale, and an example set comprising printable semi-transparent flexible organic solar cells and polyimide transparent Argon film solar cells as fully detailed herein and used with the above filed inventions demonstrates further extensions to this line of new, novel and non-obvious subject matters on knowledge eligible for Letters Patent.

### OBJECTS AND SUMMARY OF THE INVENTION

Briefly stated, novel enhanced films for absorption of light at multiplicities of different wave-lengths for plethoric applications and fabricated several different ways offer for consideration new paradigms, particularly 3D films.

According to embodiments there is provided an inventive set of novel enhanced films for absorption of light, respectively for different wave-lengths, for example of light present in white light (UV to IR, inter alia) in multiplicities of different wave-lengths, comprising, in combination: a functional material layered in a planar, flat or substantially flat configuration, curbed, curled, wrapped, twisted into helices style, coaxial, and selected from for example materials listed in Table 1, Column 6 of US2017/077867A1 (Mar. 16, 2017), said films being further comprised of at least one assembly, namely as integrated devices or individual sheets, having elements of thick/thin styled technology substrates selected from a sub-group consisting of polyamides or any chimeric or hybridized combination with any other of known or discovered equivalent materials to said sub-group elements; namely, the group consisting essentially of polyimide films, MYLAR, KAPTON (Dupont, Wilmington Del. USA) and the like materials, in tuned degrees of transparency, whereby said films are able to be run through for example means-for-deposition-onto-a-substrate types of machines and devices wherein respective layers are deposited from desired substrata, layers and members under positive pressure from an inert gas, such as argon; and wherein likewise included are heterojunction devices such that multiple bandgap materials may be deposited onto a single substrate, for example tin oxide and graphene to create transparent electrodes; complete energy conversion system elements; parts of multi-layers photovoltaics; and with multiple-dimensional cores for use with nanotechnology.

According to embodiments there is provided a basic film for providing energy by conversion of sunlight-based energy into electricity, which comprises, in combination, any combination of the below described feature set; Bidirectional absorb incoming and outgoing; broad spectrum photovoltaic (PV) 100 nm to 7000 nm; Thickness (0.048 to 0.775 mm); Length at least about 1 mm to 7 M; Fullerene and non-fullerene based HOMO, LUMO Chloronaphthalene processing agent; and Heat annealing process.

The inventive films maybe be summarized as follows:

1. Basic Film Design
a. Bidirectional absorb incoming and outgoing
b. Broad spectrum photovoltaic (PV) 100 nm to 7000 nm
c. Thickness (0.048 to 0.775 mm)
d. Length 1 mm to 7 M
e. Fullerene and non-fullerene based
f. HOMO, LUMO (https://en.wikipedia.org/wiki/HOMO/LUMO
   i. (highest occupied molecular orbital and lowest unoccupied molecular orbital)
g. Chloronapthalene processing agent (https://en.wikipendia.org/wiki/1-Chloronaphthalene)
h. Heat annealing process,

2. Hydroponic
a. Reversible wave-lengths
b. 24 hour tunable EM spectrum

3. Biological
a. Physiological
b. Mammals
   i. MRI
c. Tracking (gps)

4. Biofuel

5. Carbon Capturing systems
a. Heat
b. Bi lipid, disulfide emulsifiers

6. Computer Encryption
a. Bio records, RFID chip

7. Delta K, primer

8. Environmental
a. Pollution monitoring

9. Electronics
a. Computers (film based) (IT)

10. Energy storage (ES)

11. Geoscanning
a. Sonar

12. Medical scanning
a. Optical lenses
b. Implants

13. Misc
a. Dental
b. Security
e. Hydroponics
d. Cellular
   i. Phones
      1. Film imprintable
      2. PV, ES, IT
   ii. Cell towers
e. Marine
f. Civil lighting
   i. WiFi/GPS

14. Transportation
a. Air
b. Plane
c. Train
   i. Hyperloop

### BRIEF DESCRIPTION OF THE DRAWINGS

Various preferred embodiments are described herein with references to the drawings in which merely illustrative views are offered for consideration, whereby:

FIG. 1 is a first in a series of schematics illustrating evolution of the claimed features of the instant films of the present invention and from whence they are made, namely a bulk heterojunction material made by combining for example known systems with fullerenes;

FIG. 2 is a top plan view of the films of the present invention, showing in this case between three and seven different films, embodied in the solar inventions further described herein;

FIG. 3 is an exemplary photomicrograph table showing resultory gross surface morphology of bulk heterojunction materials;

FIG. 4 is a schematic of a solution based process for combining polymers with fullerene-based derivatives;

FIG. 5 is a prototype showing three distinct films, tuned for different wave-lengths of light, as traditionally arrayed, and in a revised specialized form developed by and or available from Solar Cubed Development (Las Vegas, Nev., USA);

FIG. 6 is a schematic of seven films being generated by an inventive process showing an end-product via Zn Oxide sputtering dispersion, nitrogen milling in an Argon atmosphere, without O2; patterning, printing inks; along with treating with and without chloronaphthalene processing to generate flexible polyimide transparent argon films.

FIG. 7 shows the closest known art, which was mechanically challenged and not ever made fully transparent or strong enough to be successful in the field;

FIG. 8 shows that artisans using the instant application as guide have made semiconducting polymer inks via a roll-to-roll process to print the evolutionary precursors of the present inventions; and

FIG. 9 shows that with, for example, 7 Argon films from the present invention, an already functional full spectrum power system can generate substantially optimized returns (available from Solar Cubed Development, Las Vegas, Nev., USA);

FIG. 10 showns exemplary steps schematized for an ink making process in at least about seven steps for an exemplary process to make select films according to the instant teachings.

Corresponding reference characters are not needed to indicate corresponding components throughout the several views of the drawings. Skilled artisans will appreciate that elements in the figures are illustrated for simplicity and clarity, and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention.

### DETAILED DESCRIPTIONS

Expressly incorporated by reference as if fully set forth herein are U.S. Pat. Nos. 9,184,317; 8,129,616; 7,186,911; 7,071,139; 7,022,910; 6,949,400; 6,913,713; 6,900,382; 6,858,158; 6,706,963 and 5,873,985; IL 248631; CA 2,959,192.

“3D Films” means those inventive 3D conductive polymer films offered for consideration by the instant teachings, functionalized as described here. 3D film is definitionally a holder of an extra dimension. Normal film has length and width it's “depth” is usually minimal based on layers and substrates. 3D film is significantly greater. It holds equal width depth and length with activity on all aspects of the film generating greater charge per mm³. Finished Cubic film is then aligned inside a capturing glass based upon energy band gaps to be captured.

Likewise, each patent and claims set incorporated expressly herein, namely each every one listed, excerpted or produced in full, from the appendix has been relied upon and differentiated such that it represents the state of the art upon which the instant application shows is the state of the art around but not within the pillars of which the instant inventions are emplaced, it is respectfully submitted.

It is respectfully submitted that the present inventor has demonstrated the ability to harvest and contain more energy than prior science has supported empirically and the solar example, based upon some of the inventive principles herein shows that this works an orders of magnitude of the ostensive improvements.

It is also the case that certain feature sets have been isolated and developed to address related issues, and the same are fully denoued for the first time herein, although the solar teachings show at least one set of ways and the amount of energy that is able to be generated using the inventive concepts and principles now explained relative to the present inventions:

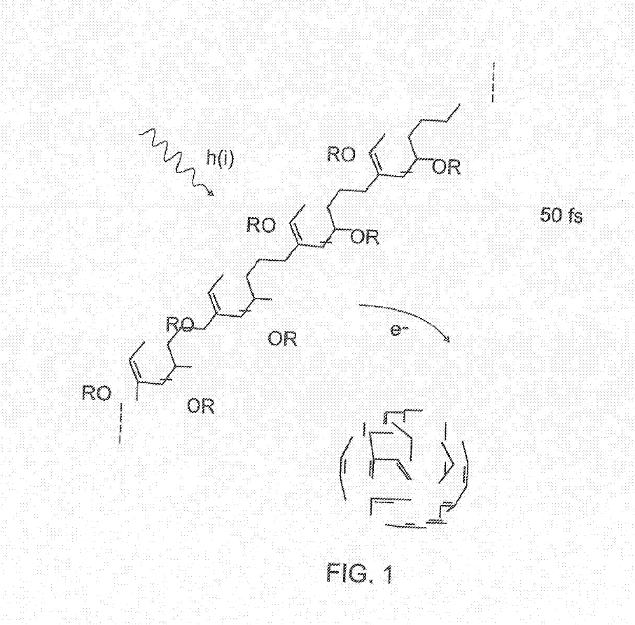

Turning now to the Figures, FIG. 1-9 schematically illustrate evolution of the state of the art which has become the films of the instant inventions, it is respectfully submitted. Referring now to FIG. 1, it is known to those skilled in the art that charges can be distributed across p/n junctions by use of bulk heterojunction material (see prior patents incorporated expressly by reference), This process was related to a Nobel Prize awarded in the last decade as shown in 1/9.

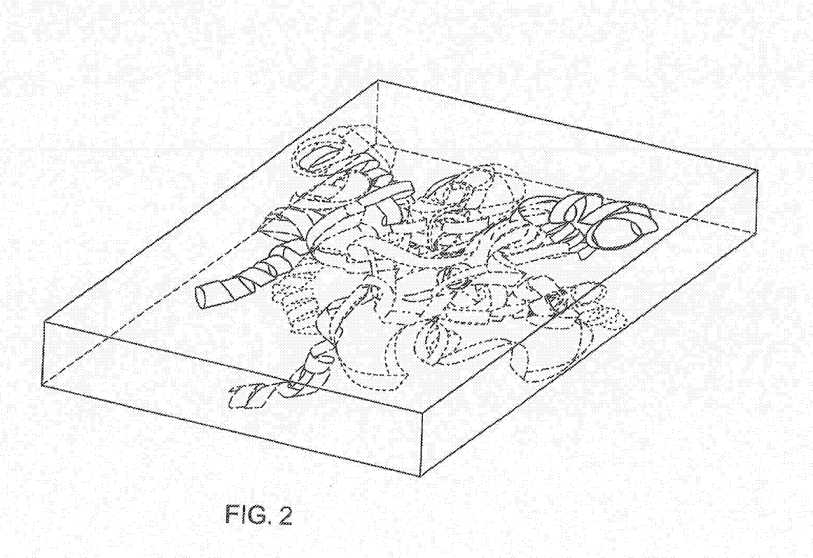

Likewise, prior to the advent of the instant teachings only “thickened” inflexible and mechanically constrained “films” could be made—FIG. 2/9 shows an example of the current films emplaced within the inventions described below. To understand what is now being done, a brief history of this part of the technology is helpful.

So, FIG. 1 is a first in a series of schematics illustrating evolution of the claimed features of the instant films of the present invention and from whence they are made, namely a bulk heterojunction material made by combining for example known systems with fullerenes.

FIG. 2 is a top plan view of the films of the present invention, showing in this case between three and seven different films, embodied in the solar inventions further described herein.

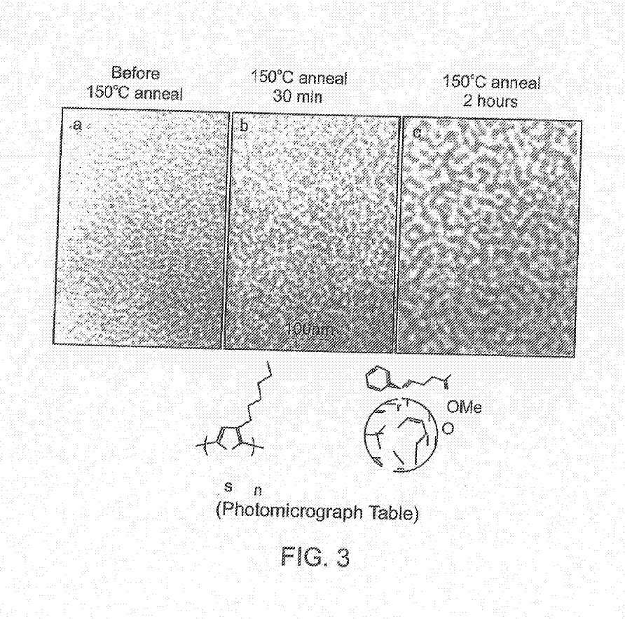

FIG. 3 is an exemplary photomicrograph table showing resultory gross surface morphology of bulk heterojunction materials.

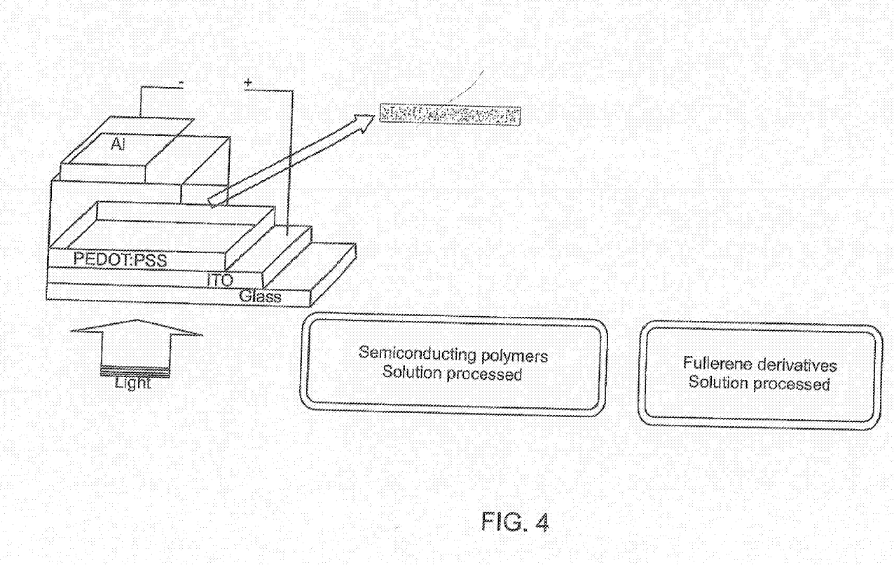

FIG. 4 is a schematic of a solution based process for combining polymers with fullerene-based derivatives.

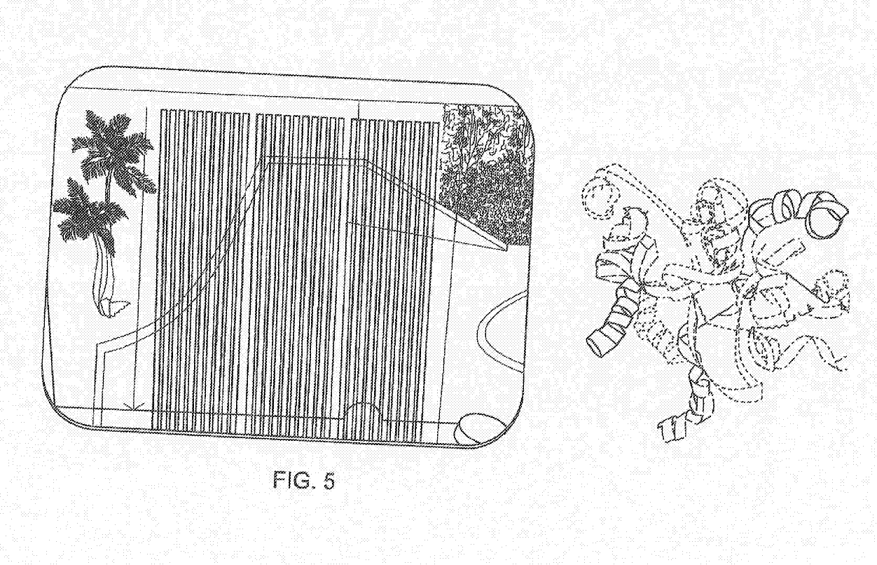

FIG. 5 is a prototype showing three distinct films, tuned for different wave-lengths of light, as traditionally arrayed, and in a revised specialized form developed by and or available from Solar Cubed Development (Las Vegas, Nev., USA).

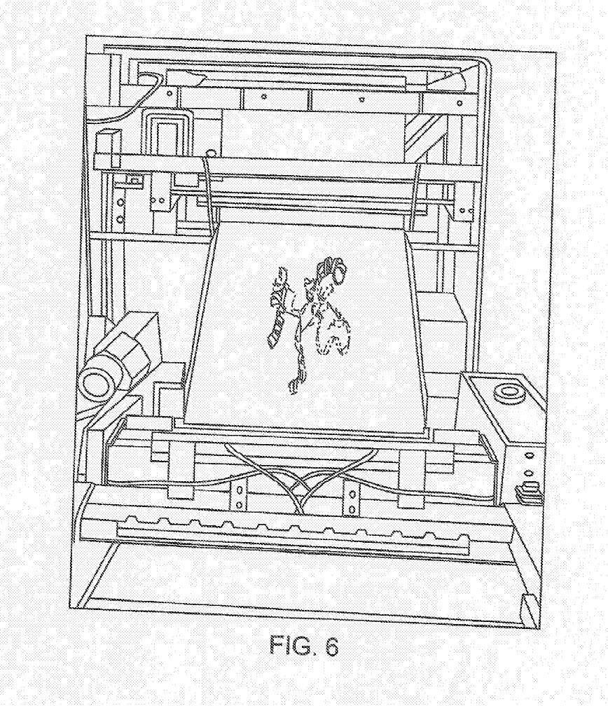

FIG. 6 is a schematic of seven films being generated by an inventive process showing an end-product via Zn Oxide sputtering dispersion, nitrogen milling in an Argon atmosphere, without O2; patterning, printing inks; along with treating with chloronaphthalene processing to generate flexible polyimide transparent argon films.

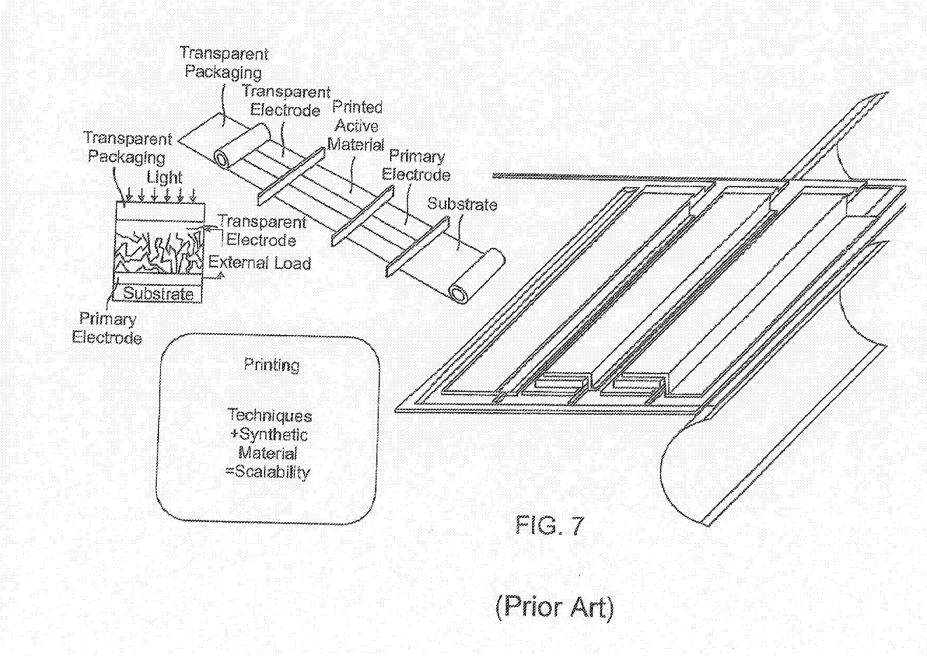

FIG. 7 shows the closest known art, which was mechanically challenged and not ever made fully transparent or strong enough to be successful in the field.

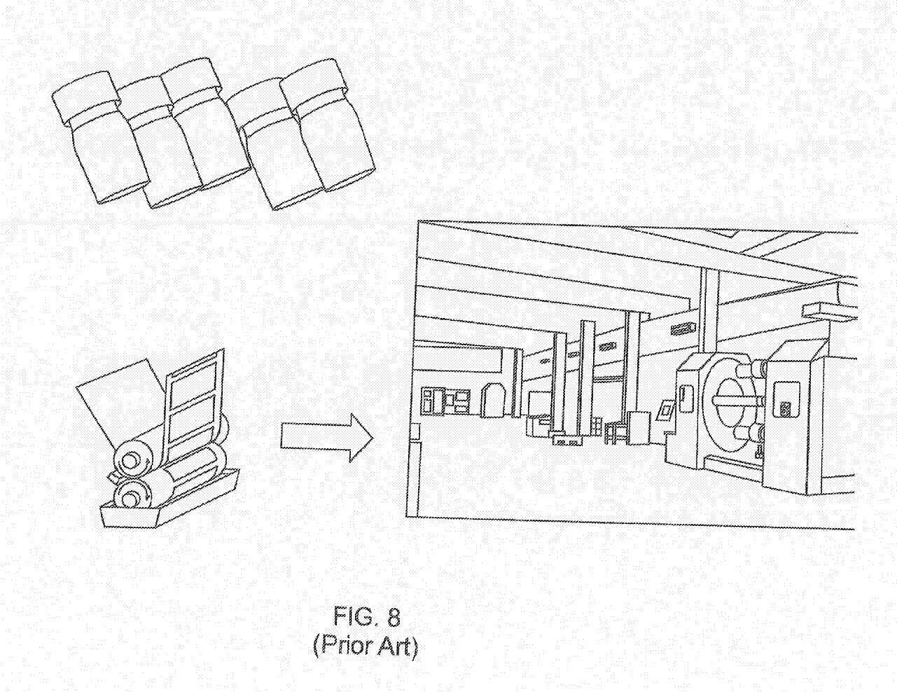

FIG. 8 shows that semiconducting polymer inks can be used to roll-to-roll print the evolutionary precursors of the present inventions.

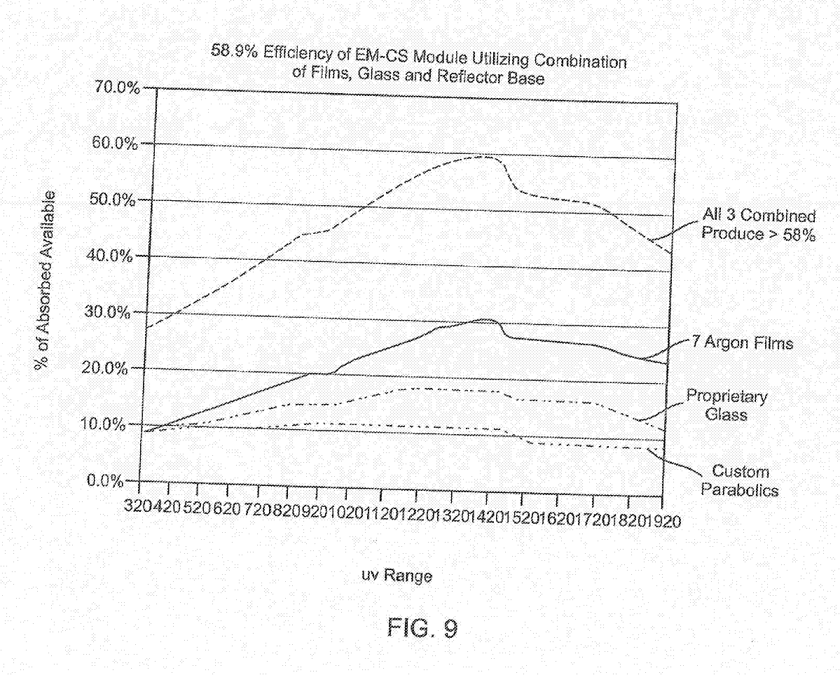

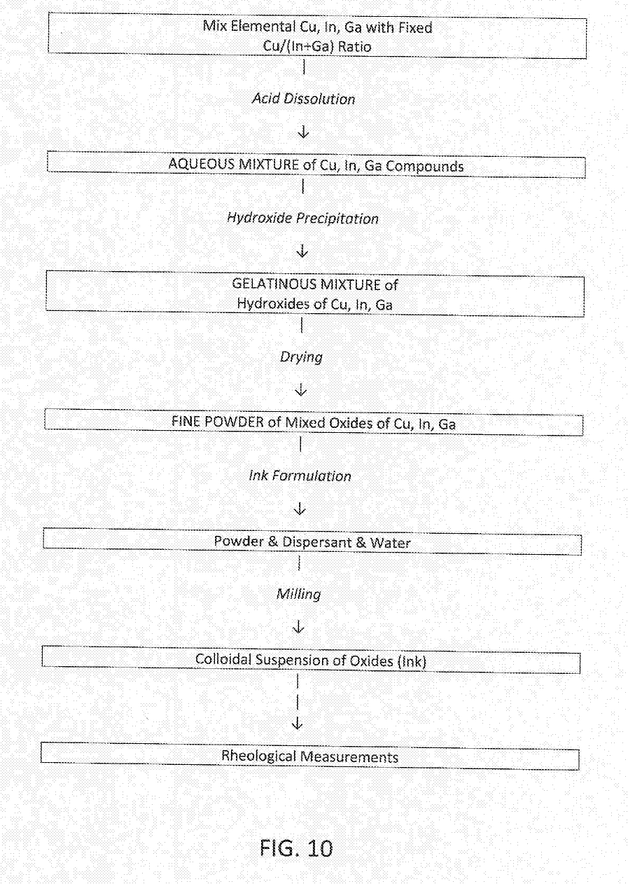

FIG. 9 shows that with, for example, 7 Argon films from the present invention, an already functional full spectrum power system can generate substantially optimized returns (available from Solar Cubed Development, Las Vegas, Nev., USA). FIG. 10 shows a schematic example of how a scalable and industrially efficient system has evolved by focus upon at least about seven key steps for generating ink-based semiconducting films according to the instant teachings.

And now to explain how an example from alternative energy such as solar might help if needed sources were able to meet demand. While revenue in the photovoltaic (PV) solar power industry approaches $100 billion annually, PV technology requires huge capital investment that pays off slowly at best. Existing PV cells are deployed as flat panels of material that—at best—produce about 0.200 kW per square meter. On a sunny day, a solar cell the size of a card table could keep six light bulbs lit up, for as long as the sun is shining. For some background on PV cells, see U.S. Pat. No. 8,093,492 to Hering and U.S. Pat. No. 6,689,949 to Ottabasi.

The invention using films provides a cell that captures energy from electromagnetic radiation (EMR) and can provide that energy as electricity. The cell captures energy from a broader spectrum of EMR than conventional systems, namely the EV range which extends from ultraviolet to beyond infrared. The cell includes a composition of material that interacts with the EMR across three dimensions of space, exploiting the insight that EMR exerts energy across three independent dimensions—a first dimension defined by a direction of change of a magnetic field B, a second dimension of changing electric field E, and a third dimension being the direction of a propagation of the EMR. By using inward reflectors, the cell captures the EMR internally. By using a 3D medium, the cell maximizes its potential interactions with, and potential for capturing energy from, the EMR. The cell includes a composition of materials characterized by multiple bandgaps. Internal EMR from across a broad electromagnetic spectrum energizes electrons of those materials from the valence bands to the conduction bands, which can be harvested as electric current using the included electrodes.

By including a curved upper surface geometry with absorptive surface and prismatic focusing, a cell captures EMR energy for a great duration of each day even, in fact, when it is not strictly speaking daylight, the cell captures all forms of light, indirect, reflected, diffused, refracted and prismatic. By the described features and phenomena, cells of the invention maximize the EMR spectrum from which energy is captured, and the efficiency of capture of that energy, and the duration of capture per day. For at least those reasons, cells of the invention exhibit very high efficiency and may in fact provide at least about 2.9 kWb per m³ of power or more.

Due to the high efficiency and power production provided by cells of the invention, people's demand for energy may be met without producing stoichiometric amounts of carbon dioxide and without exacerbating geo-political tensions surrounding unequal distribution of hydro-carbon fuels. Thus systems and methods of the invention provide tools for meeting global energy demand without heaping on the human suffering. Using systems and methods of the invention, people may read at night, travel, operate their business, and continue to conduct their lives in a manner that is enjoyable and sustainable.

Additionally, the glass encasement is managed including antireflective (AR) coating on the outer surface of the glass and an oxide coating on the inner surface of the glass, inter alia. The antireflective coating can be added to reduce the amount of reflections off of the outer surface as compared to an uncoated glass. The oxide coating on the inner surface can be provided to perform various functions. For example, the oxide coating can be provided to prismatically divide the light into its constituent spectral components. This allows incoming light to be separated into spectral components and the spectral components to be directed at different directions from the inner surface of the glass.

The oxide coating can also act as a semi-permeable membrane, allowing radiation in, but, inhibiting its exit. This can facilitate the reuse of photons that are not absorbed and converted on their first pass through the materials. With the appropriate doping and other characteristics as described, embodiments can be implemented that achieve the delivery to the bandgap materials of 58.86% of direct light impinging on the glass, and delivery to the bandgap materials of up to 30% of indirect light impinging on the glass. This can be achieved because light impinging on the glass at a shallow angle can be captured rather than reflected, and then can be refracted towards the photovoltaic bandgap materials located within the central region of the glass encasement.

According to instant teachings, light impinging on the glass at a shallow angle can be captured rather than reflected. The shape of the glass housing is important to increasing the efficiency of the system and the range of the electromagnetic spectrum that can be captured by the system. The shape is not limited to that shown in the figures. Various shapes of glass enclosure can be used, however, in some embodiments, a rounded shape is used to present a more direct angle to the source of the electromagnetic energy (e.g., the sun, a lamp, or other energy source) and to facilitate refraction of the light toward the photovoltaic materials.

In one aspect, the invention provides an improved high efficiency electromagnetic energy capturing system (EM-CS). The EM-CS includes a cell.

FIG. 1 and FIG. 2 each shows use of polymer systems and nanotechnology to generate products of the present invention. Numerous shapes and configurations of the films of the present invention can be modified for particular applications as shown in FIG. 2 and FIG. 3. FIG. 4 schematizes some combinations of subject materials. FIG. 5 shows ribbons and films disposed in air and on a hybrid—see through platform. FIG. 6 shows a new process for making two and 3D films, while FIG. 7 and FIG. 8 show how two-dimensional film processes led to the evolution of 3 dimensional films. FIG. 9 shows a solar application of said films and data regarding same. FIG. 10 shows a process schematic used for scalable to produce inks to render the films semiconductive at various tunable wave-lengths.

Systems using solar harvesting are now known based energy upon inventor's PCT/US2015/032148; useful to provide the capture of direct light during times of sunrise and sunset when energy from the sun is impinging on the glass at low angles of inclination to the earth. In other embodiments, the glass housing is configured in a flower-petal like shape to present a normal surface to the sun's rays as the sun moves across the sky during the day.

Providing multiple materials with multiple band gaps allows the unit to respond to multiple different wave-lengths of the spectrum. In some embodiments, the photo-voltaic stack includes 2 to 4 layers of bandgap materials each having a different bandgap energy. In other embodiments, other numbers of layers of bandgap materials can be provided, including a single layer stack of more than 4 layers. Marginal returns may diminish with increasing number of layers depending on a number of factors including, for example, the spectrum of available electromagnetic energy, the transparency and absorption efficiency of the various materials in the stack, the amount of internal reflection that can be achieved to contain capture photons, and so on. In operation, the outer bandgap material of the photovoltaic stack captures the photons it can at the wave-lengths associated with its bandgap energy and converts those into electric current.

Those photons not captured by the first layer, pass through to subsequent layers until they are captured, absorbed, reflected off the surface of a subsequent layer, or pass through the stack and are reflected off of the reflective surfaces of the glass enclosure, A portion of the reflected photons reach the photovoltaic stack again providing the opportunity for these otherwise lost photons to be captured and converted to electric current. The multi-leveled, multi-band gapped thick film can be bendable and may incorporate different materials having different band gaps optimized for different wave-lengths of light present in white light (including for instance ultraviolet and infrared light), and for different wave-lengths of light that occur at different times. For instance, during sunrise and sunset the spectrum of light is different from that of mid-day, so different materials may be provided with different band gaps to capture as much of the energy of those different types of light as possible. In one example embodiment the different materials may comprise GaAs, Ge, Si and GainP2, for instance. In other embodiments materials such as GaS, GIP,GIA, InGa, CdTe, CIGS, CdTe/CdS, CuinSe2, GIN, ZMT, and/or CdS, may be used. In some embodiments, the band gaps of the materials are selected such that there are overlapping bands to achieve energy conversion from the most dense regions of the spectrum. In some embodiments, the chemical compositions of the materials can be varied to tune the bandgaps of the junctions.

Table 1 illustrates another example of different materials that can be used along with their associated band gaps and estimated conversion efficiencies using 2 or more layers. Artisans understand the exemplary numbers are lowered in this example due to overlap.

TABLE 1

| | | |
|---|---|---|
| InN (ZnS; ZnSe) | 3.6 Ev | 8.00% |
| CIGS (CdS; | 2.4 Ev | 19.01% |
| InGaAs) InGaAsP | 1.84 Ev | 15.02% |
| (GaP; InGaP) | 1.44 Ev | 16.06% |
| CdTe (GaAs) | 1.12 Ev | 18.78% |
| c-Si (GaAs; | 0.92 Ev | 9.05% |
| InGaAs) InGaAs | 0.70 Ev | 6.02% |
| (a-Si; H; GalnP) Ge | | |
| (InAs; GaSb; InSb) | | |

In various example embodiments two, three, four or five layers of unique thick films may be provided that can gather photons on either side of the film, each of which may in certain embodiments vary from about 0.03 to 5.0 microns in thickness. The length and width of the films can be of suitable dimensions depending on the available dimensions and volume of the enclosure. The length and width can also be chosen based on the manner in which the films are layered within the enclosure. For example, in some embodiments, the films can be layered in a planar or flat (or substantially flat) configuration within the enclosure. In other embodiments, the films can be curved or curled or wrapped, and layered within the enclosure in a coaxial or substantially coaxial fashion. For example, flexible layers can be used with sufficient resilience such that when inserted into the enclosure they conform to the inner contour of the enclosure. Accordingly, the films can be configured to take the shape of the enclosure. Where design issues have traditionally been seen to limit the width of the film, ribbon-like lengths of film can be wound (e.g. in a helical fashion) within one another inside the enclosure. The multiple-layer translucent photovoltaic stack may be electrically connected with a positive charge for ionic collection.

As noted above, in various embodiments the multiple layers of bandgap materials can be fabricated whether as an integrated device or as individual sheets, using thick film technology. In examples, polyamides, a thick film substrate such as Mylar, KAPTON, TEDLAR or any other polyimide film (available from DuPont, Wilmington Del. USA), or other film can be used as a substrate, such materials are available in varying degrees of transparency. The substrate sheet can be run through a deposition device (e.g. using chemical vapot deposition or CVD) or other like device in which the layers of the device are deposited onto the substrate. In addition to chemical vapor deposition, other techniques such as, for example, Extrusion Positive Printing, VPD, Sputtering, and the like can be used to lay down the various layers.

For example, in such a process the electrode layers and semiconductor layers can be deposited onto the sub-strate to produce the thick film photovoltaic material. The fabrication device can be maintained with a positive pressure using an inert gas such as, for example, argon, to keep the chamber relatively free or completely free of oxygen. This can avoid the detrimental effects of oxidation on the materials. Where bandgap materials are fabricated on individual sheets, a single junction device can be fabricated on a given substrate.

On the other hand, wherein heterojunction polymeric and chimeric devices are desired, multiple bandgap materials can be deposited onto a single substrate. Where desired, indium tin oxide, graphing, or other like materials can be used to create transparent electrodes. The various aspects of the disclosed technology may be used individually or in various combinations, including in complete energy conversion systems comprising: a capture cell (in which photons may be more completely retained giving rise to a greater degree of energy absorption and conversion); a multi-layered photovoltaic system, a unique thick-film processing technology; the utilization of multigap material for greater access to the light spectrum (hence greater exposure and greater absorption of photons); and with a multi-dimensional core for use with nanotechnology is being (dots, lattice) GPS and various sensor, storage usages and ozone creation. In addition, the ability to capture indirect lighting from the angle and type of glass formulations increases the total overall energy wattage of the system. The use of capture cells with multiple levels of collecting film 300 may incorporate all of the above technologies to create a multi-layered, multi-band gap, bidirectional photovoltaic film core. The capture cell can work with the thick film by increasing the amount at light exposure that can provide photonic absorption, and by increasing the number of photon passes through the band gap material.

The thick film avoids problems in thin film technology; it is more stable and still allows for transparency for photons to pass through multiple absorption layers with multiple band gap materials. The present photovoltaic system can be used to generate a flow of electrons (an electric current) where there is sunlight or another source of electromagnetic radiation or wave-lengths. The present photovoltaic system can be used on or in homes, commercial buildings, industrial applications, automobiles, or any other form of transportation. The system can be portable, as it is highly efficient and can be used anywhere that energy is needed. The band gap of a material is the energy required to excite an atom of that material sufficiently to move one of its electrons from a lower energy state, or band, to a higher energy state, or band.

Only photons with energy levels greater than that of the band gap can excite electrons to move from the valence band to the conduction band, where they can flow and create electricity. For materials with lower band gaps, a greater range of light frequencies will have sufficiently high energies to excite electrons in those materials to move from the valence band to the conduction band (this helps determine Valence band material). Moreover, there are various “tunable” materials, such as InGap or CIGS. Therefore, the smaller the band gap of a material, the more easily light striking that material may be converted to electricity. But when the band gap is too small, the negatively-charged electrons in the conduction band recombine too easily with the positively-charged atoms they left behind (i.e., “holes”), such that maintaining a flow of electrons (i.e., an electrical current) becomes difficult.

Because different frequencies of light carry different levels of energy, materials with different band gaps may be provided to capture the different frequencies of light within a spectrum to optimize the total amount of energy obtainable from the spectrum. Band gaps are selected that are not only efficient at a certain wave-lengths, but also that gather the most total electrons, keeping in mind that higher frequency light carries more energy. Some examples of band gaps are: Silicon's band gap is 1.11-1.12 eV; Selenium's is 1.5-1.6 eV; GaAs Gallium/Arsenic's is 1.3-1.4 eV; CuO cupric/Oxide's is 2.0 eV; GaTe is 1.4 eV; AlAs Aluminum/Arsenic's is 2.3 eV. Light also has specific unique wave-lengths.

For example, Red is 622-780 nm; Orange is 622-597 nm; Infrared A is 700-1400 nm; Infrared B is 1400-3000 nm; and lnfrared C is 3000-10000 nm. Accordingly, Silicon could theoretically convert 100% of the photons having a wave-length-equivalent to its 1.11-1.12 eV band gap, while also converting a lower percentage of photons having a shorter wave-lengths and higher energy. However, photons of light having a wave-lengths over 1.12 eV will not generate any electricity in Silicon, because these longer wave-lengths photons have less than the minimum level of energy needed to overcome Silicon's 1.11-1.12 eV band gap.

In practice, conventional solar cells using Silicon have had actual conversion efficiencies ranging from about 12% to 14%. That is, only about 12% to about 14% of the energy in the photons hitting conventional Silicon solar cells is converted to electricity (the same range as Hoffman produced in 1960 or 54 years ago). The use of tunable PV material, i.e., InGS(N)(P), CIGS, GaAs, AlGeN, changes this. By pushing the formula higher in the Se one can manipulate both the band gap and adjust for the “holes.” Hence, if using Si provides a range of at least about 1,112-800 eV (with the latter giving way to more holes) then one can tune the other separate layers to cover 850-600 and 650-315, thus, covering the highest gradient of energy (from IRc-UVb).

Furthermore, the described features, structures, or characteristics of the invention may be combined in any suitable manner in one or more embodiments. In the following description, numerous specific details are provided to provide a thorough understanding of embodiments of the invention. One skilled in the relevant art will recognize, however, that the invention may be practiced without one or more of the specific details, or with other methods, components, materials, and so forth. In other instances, well-known structures, materials, or operations are not shown of described in detail to avoid obscuring aspects of the invention.

Any schematics and/or flow chart diagrams along with verbal descriptions of steps, included herein are generally set forth as either linguistic or pictorial logical flow chart diagrams. As such, the depicted order and labeled steps are indicative of one embodiment of the presented method. Other steps and methods may be conceived that are equivalent in function, logic, or effect to one or more steps, or portions thereof, of the illustrated systems, processes or methods.

Additionally, any format and/or symbols employed are provided to explain the logical steps of associated systems, processes and methods and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a step is suggested does not indicate that it needs to be performed prior to or after another step unless expressly set forth.

Legacy or historical attempts to address these issues also have some value, in defining the state of the art, and paucity of improved applications to overcome the science.

While methods, devices, compositions, and the like, have been described in terms of what are presently considered to be the most practical and preferred implementations, it is to be understood that the disclosure need not be limited to the disclosed implementations. It is intended to cover various modifications and similar arrangements included within the spirit and scope of the claims, the scope of which should be accorded the broadest interpretation so as to encompass all such modifications and similar structures. The present disclosure includes any and all implementations of the following claims. It is understood that the term, present disclosure, in the content of a description of a component, characteristic, or step, of one particular embodiment of the disclosure, does not imply or mean that all embodiments of the disclosure comprise that particular component, characteristic, or step.

It should also be understood that a variety of changes may be made without departing from the essence of the disclosure. Such changes are also implicitly included in the description. They still fall within the scope of this disclosure. It should be understood that this disclosure is intended to yield a patent covering numerous aspects of the disclosure both independently and as an overall system and in both method and apparatus modes.

Further, each of the various elements of the disclosure and claims may also be achieved in a variety of manners. This disclosure should be understood to encompass each such variation, be it a variation of an implementation of any apparatus implementation, a method or process implementation, or even merely a variation of any element of these.

Particularly, it should be understood that as the disclosure relates to elements of the disclosure, the words for each element may be expressed by equivalent apparatus terms or method terms-even if only the function or result is the same.

While several embodiments of the present disclosure have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present disclosure. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present disclosure is/are used.

Those skilled in the art will recognize, or be able to ascertain using no more than routine experimentation, many equivalents to the specific embodiments of the disclosure described herein. It is, therefore, to be understood that the foregoing embodiments are presented by way of example only and that, within the scope of the appended claims and equivalents thereto, the disclosure may be practiced otherwise than as specifically described and claimed. The present disclosure is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one,” The phrase “and/or,” as used herein in the specification and in the claims, should be understood to mean “either at both” of the elements so conjoined, i.e., elements that are conjunctively present in some eases and disjunctively present in other cases. Other elements may optionally be present other than the elements specifically identified by the “and/or” clause, whether related or unrelated to those elements specifically identified, unless clearly indicated to the contrary.

Reference throughout this specification to “one embodiment” or “an embodiment” means that a particular feature, structure, or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

Reference throughout this specification to “one embodiment,” “an embodiment,” or similar language mans that a particular feature, structure, or characteristic described in connection with the embodiment is included in at least one embodiment of the present invention. Thus, appearances of the phrases “in one embodiment,” “in an embodiment,” and similar throughout this specification may, but do not necessarily, all refer to the same embodiment.

Furthermore, the described features, structures, or characteristics of the invention may be combined in any suitable manner in one or more embodiments. In the following description, numerous specific details are provided to provide a thorough understanding of embodiments of the invention. One skilled in the relevant art will recognize, however, that the invention may be practiced without one or more of the specific details, or with other methods, components, materials, and so forth. In other instances, well-known structures, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown. Unless otherwise indicated, all numbers expressing quantities of ingredients, properties such as molecular weight, reaction conditions, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained by the present invention. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements.

The terms “a,” “an,” “the” and similar referents used in the context of describing the invention (especially in the context of the following claims) are to be construed to cover both the singular and the plural, unless otherwise indicated herein or clearly contradicted by context. Recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs the specification is deemed to contain the group as modified thus fulfilling the written description of all Markush groups used in the appended claims.

Certain embodiments of this invention are described herein, including the best mode known to the inventors for carrying out the invention. Of course, variations on these described embodiments will become apparent to those of ordinary skill in the art upon reading the foregoing description. The inventor expects skilled artisans to employ such variations as appropriate, and the inventors intend for the invention to be practiced otherwise than specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein of otherwise clearly contradicted by context.

Specific embodiments disclosed herein may be further limited in the claims using consisting of or consisting essentially of language. When used in the claims, whether as filed or added per amendment, the transition term “consisting of” excludes any element, step, or ingredient not specified in the claims. The transition term “consisting essentially of” limits the scope of a claim to the specified materials or steps and those that do not materially affect the basic and novel characteristic(s). Embodiments of the invention so claimed are inherently or expressly described and enabled herein.

As one skilled in the art would recognize as necessary or best-suited for performance of the methods of the invention, a computer system or machines of the invention include one or more processors (e.g., a central processing unit (CPU) a graphics processing unit (GPU) or both), a main memory and a static memory, which communicate with each other via a bus.

A processor may be provided by one or more processors including, for example, one or more of a single core or multi-core processor (e.g., AMD Phenom II X2, Intel Core Duo, AMD Phenom II X4, Intel Core i5, Intel Core I & Extreme Edition 980X, or Intel Xeon E7-2820).

An I/O mechanism may include a video display unit (e.g., a liquid crystal display (LCD) or a cathode ray tube (CRT)), an alphanumeric input device (e.g., a keyboard), a cursor control device (e.g., a mouse), a disk drive unit, a signal generation device (e.g., a speaker), an accelerometer, a microphone, a cellular radio frequency antenna, and a network interface device (e.g., a network interface card (NIC), Wi-Fi card, cellular modem, data jack, Ethernet port, modem jack, HDMI port, mini-HDMI port, USB port), touchscreen (e.g., CRT, LCD, LED, AMOLED, Super AMOLED), pointing device, trackpad, light (e.g., LED), light/image projection device, or a combination thereof.

Memory according to the invention refers to a non-transitory memory which is provided by one or more tangible devices which preferably include one or more machine-readable medium on which is stored one or more sets of instructions (e.g., software) embodying any one or more of the methodologies or functions described herein. The software may also reside, completely or at least partially, within the main memory, processor, or both during execution thereof by a computer within system, the main memory and the processor also constituting machine-readable media. The software may further be transmitted or received over a network via the network interface device.

While the machine-readable medium can in an exemplary embodiment be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding or carrying a set of instructions for execution by the machine and that cause the machine to perform any one or more of the methodologies of the present invention. Memory may be, for example, one or more of a hard disk drive, solid state drive (SSD), an optical disc, flash memory, zip disk, tape drive, “cloud” storage location, or a combination thereof. In certain embodiments, a device of the invention includes a tangible, non-transitory computer readable medium for memory. Exemplary devices for use as memory include semiconductor memory devices, (e.g., EPROM, EEPROM, solid state drive (SSD), and flash memory devices e.g., SD, micro SD, SDXC, SDIO, SDHC cards); magnetic disks, (e.g., internal hard disks or removable disks); and optical disks (e.g., CD and DVD disks).

Furthermore, numerous references have been made to patents and printed publications throughout this specification. Each of the above-cited references and printed publications are individually incorporated herein by reference in their entirety.

In closing, it is to be understood that the embodiments of the invention disclosed herein are illustrative of the principles of the present invention. Other modifications that may be employed are within the scope of the invention. Thus, by way of example, but not of limitation, alternative configurations of the present invention may be utilized in accordance with the teachings herein. Accordingly, the present invention is not limited to that precisely as shown and described.

What is claimed is:

1. 3D conductive polymer films further comprised of bulk heterojunctional polymeric and functionalized elements effective for efficiency gains in conversion of EMR to electricity.

2. The films of claim 1, further comprising dense-packed states meaning said 3D films are further arrayed within any simple or complex polyhedral package, as shown and described.

3. The films of claim 2, further comprising effective absorption of tunable wave-lengths to achieve results within predetermined power spectra.

4. The films of claim 3, further comprising a process of Zinc Oxide dispersion, or any known or later developed functional equivalent, in programmed dimensional configurations using special processing units.

5. The films of claim 4, further comprising being made by a process of Oxygen-free nitrogen milling in an Argon atmosphere.

6. The films of claim 5, further comprising being made by a process of printing organic semiconductors, in a way functionally equivalent to roll-to-roll or roll to roll.

7. The films of claim 6, further comprising a finishing process using chloronaphthalene for generating transparent resultants.

8. Two and 3D films for absorption of light, respectively for different wave-lengths, for example of light present in white light (<100 nm to 7000 nm) in multiplicities of different wave-lengths, comprising, in combination: a functional material layered in at least one geometry selected from the group of planar, flat or substantially flat configuration, curved, curled, wrapped, twisted into helices style, coaxial, orb-like, simulacra of proteinaceous folder and non-folded metrices, ribbon like and amorphously arrayed along axis in three ordinal planes.

9. Two and 3D films, as defined in claim 8, said films being further comprised of at least one assembly, namely as integrated devices or individual sheets, having elements of thick/thin styled technology substrates selected from a sub-group consisting of polyamides or any chimeric or hybridized combination with any other of known or discovered equivalent materials to said sub-group elements; namely, the group consisting essentially of polyimide films, MYLAR, KAPTON (Dupont, Wilmington Del. USA) and the like materials, in tuned degrees of transparency.

10. Two and 3D films, as defined in claim 9, wherein said films are able to be run through for example means-for-deposition-onto-a-substrate types of machines and devices wherein respective layers are deposited from desired substrata, layers and members under positive pressure from an inert gas, such as argon.

11. Two and 3D films, as defined in claim 10, and wherein likewise included are heterojunction devices such that multiple bandgap materials may be deposited onto a single substrate, for example tin oxide and graphene to create transparent electrodes; complete energy conversion system elements; parts of multi-layers photovoltaics; and with multiple-dimensional cores for use with nanotechnology.

12. Improved two and 3D films, films as used for applications comprising at least one of Biofuel; hydroponics; physiological mammal monitoring and modeling; drones and defense applications of the same; automobiles; above water and under water craft; space craft; satellites; and weapons.

13. Improved films as defined in claim 8, used for applications comprising Carbon Capturing systems, further comprising specific modification for:
i. Heat
ii. Bi lipid, disulfide, emulsifiers

14. Improved films as defined in claim 8, and disclosed herein used for applications comprising Computer Encryption
i. Bio records, RFID chips.

15. Improved films as defined in claim 8, used for applications comprising:
Delta K, primer

16. Improved films as defined in claim 8, used for applications comprising:
Environmental
i. Pollution monitoring

17. Improved films as defined in claim 8, used for applications comprising: Electronics
i. Computers (film based) (IT).

18. Improved films as defined in claim 8, used for applications comprising:
Energy storage (ES)

19. Improved films as defined in claim 8, used for applications comprising: Geoscanning
i. Sonar

20. Improved films as defined in claim 8, used for applications comprising: Medical scanning
i. Optical lenses
ii. Implants

21. Improved films as defined in claim 8, and disclosed herein used for applications comprising:
i. Dental
ii. Security
iii. Desalination and farming
iv. Cellular
v. AR/VR.
i. Phones
1. Film imprintable
2. PV, ES, IT
ii. Cell towers

22. Improved films as defined in claim 8, used for applications comprising Marine
i. Civil lighting
i. WiFi/GFS

23. Improved films as defined in claim 8, and disclosed herein used for applications comprising Transportation
i. Air
ii. Plane
iii. Train
i. Hyperloop

24. A process for making enhanced film technologies, comprising, in combination:
Creating thin films effective to absorb specific wave-lengths of light; by printing flexible thin and lightweight films, in predetermined widths roll-to-roll via Zn Oxide sputtering dispersion, or the equivalent steps, from a related process;
nitrogen milling in an Argon atmosphere, without O₂; patterning; and, printing inks;
along with optionally treating wife chloronaphthalene processing to generate flexible polyimide transparent argon films.

25. The process of claims 24, further comprising an ink making process of at least about seven steps for select elements of precursor inks used for said films.

26. The process of claim 24, whereby said films are less sensitive to the angle of solar incidence then known films, and absorb specific wave-lengths of light as well a broad spectrum.

27. The process of claim 24, further comprising thick film technology with a positive thermal energy coefficient.

28. The process of claim 24, adapted for low light sensitivity (indoor and outdoor).

29. The process of claim 24, resulting product being semi or wholly transparent.

30. The process of claim 25, further comprising electronic functionality in whole or in part from inks printed on said films.

31. Films of claim 30, whereby the p-n junction created by bulk heterojunction polymers increases efficiency past a 50% NREL certification, 3D film is definitionally a holder of an extra dimension, normal film has length and width it's “depth” is usually minimal based on layers and substrates, 3D film is significantly greater, it holds equal width depth and length with activity on all aspects of the film generating greater charge per mm³, finished Cubic film is then aligned inside a capturing glass based upon energy band gaps to be captured for solar energy harvesting applications, inter alia.

32. The films of claim 6, further comprising a finishing process without using chloronaphthalene for generating transparent resultants.
